(19) United States
(12) Patent Application Publication
(10) Pub. No.: US 2026/0302717 A1
(43) Pub. Date: Oct. 1, 2026

(54) OPTICAL NONRECIPROCAL DEVICE AND OPTICAL CIRCUIT

(71) Applicant: NICHIA CORPORATION, Anan-shi (JP)

(72) Inventors: Koji USAMI, Kawasaki-shi (JP); Masanori OKADA, Yokohama-shi (JP)

(73) Assignee: NICHIA CORPORATION, Anan-shi (JP)

(21) Appl. No.: 19/629,580

(22) Filed: Mar. 26, 2026

(30) Foreign Application Priority Data
Mar. 28, 2025 (JP) 2025-057090

(51) Int. Cl. H01S 5/00; H01S 3/083; H01S 5/14; H01S 5/20

(52) U.S. Cl. CPC H01S 5/0064; H01S 3/083; H01S 5/14; H01S 5/2018

(57) ABSTRACT

An optical nonreciprocal device includes: a passive waveguide having a first lateral surface, a second lateral surface opposite the first lateral surface, and an upper surface connecting the first lateral surface and the second lateral surface, the passive waveguide including: a first clad, a second clad, and a core between the first clad and the second clad; and a ferromagnet continuously covering the first lateral surface, the second lateral surface, and the upper surface of the passive waveguide. In a cross section perpendicular to an optical axis of the passive waveguide, the core, a portion of the ferromagnet covering the first lateral surface, and a portion of the ferromagnet covering the second lateral surface overlap in a direction perpendicular to a stacking direction of the first clad, the core, and the second clad.

### CROSS-REFERENCE TO RELATED APPLICATION

This application claims priority to Japanese Patent Application No. 2025-057090, filed on Mar. 28, 2025, the disclosure of which is hereby incorporated by reference in its entirety.

### TECHNICAL FIELD

The present disclosure relates to an optical nonreciprocal device and an optical circuit.

### BACKGROUND

A semiconductor optical isolator having a ferromagnet disposed on a lateral surface or the upper surface of an optical waveguide formed of semiconductor layers including an active layer has been known (see, for example, Japanese Patent Publication No. 2010-123688 (“Patent Literature 1”)).

### SUMMARY

Providing a ferromagnet on a lateral surface or an upper surface of an optical waveguide makes propagation loss of the light propagating in two opposing directions greater in one direction than the other. In other words, the nonreciprocal losses realize an optical nonreciprocal device having optical nonreciprocity. However, in an optical isolator employing an optical waveguide that includes an active layer, the loss component caused by the absorption of light in the active layer (i.e., reciprocal loss) is greater than the nonreciprocal loss thereby weaken the optical nonreciprocity.

An object of the present disclosure is to provide an optical nonreciprocal device having strong optical nonreciprocity and an optical circuit.

According to one embodiment of the present disclosure, an optical nonreciprocal device includes a passive waveguide having a first clad, a second clad, and a core disposed between the first clad and the second clad; and a ferromagnet continuously covering a first lateral surface, a second lateral surface located opposite the first lateral surface, and an upper surface connecting the first lateral surface and the second lateral surface of the passive waveguide. In a cross section perpendicular to the optical axis of the passive waveguide, the core, a portion of the ferromagnet covering the first lateral surface, and a portion of the ferromagnet covering the second lateral surface overlap in the direction perpendicular to the stacking direction of the first clad, the core, and the second clad.

According to another embodiment of the present disclosure, an optical circuit includes a semiconductor laser element, an optical waveguide optically coupled to the semiconductor laser element, a ring resonator optically coupled to the optical waveguide, and the optical nonreciprocal device described above that is disposed on at least one portion of the ring resonator.

According to another embodiment of the present disclosure, an optical circuit includes a semiconductor laser element part which has a first end surface and a second end surface located opposite the first end surface, an optical waveguide connecting the first end surface and the second end surface, and the optical nonreciprocal device described above disposed on at least one portion of the optical waveguide, wherein the semiconductor laser element part and the optical waveguide constitute a ring laser.

According to another embodiment of the present disclosure, an optical circuit having a semiconductor laser element part which has a first end surface and a second end surface located opposite the first end surface, a first optical waveguide optically coupled to the semiconductor laser element part at the first end surface, a second optical waveguide optically coupled to the semiconductor laser element part at the second end surface, a ring resonator optically coupled to the first optical waveguide and the second optical waveguide, and the optical nonreciprocal device described above that is disposed on at least one portion of the first optical waveguide and/or the second optical waveguide.

According to certain embodiments of the present disclosure, optical nonreciprocity can be strengthened.

### BRIEF DESCRIPTION OF THE DRAWINGS

FIG. 1 is a cross-sectional view of an optical nonreciprocal device according to a first embodiment.

FIG. 2 is a cross-sectional view showing a method of manufacturing the optical nonreciprocal device according to the first embodiment.

FIG. 3 is a cross-sectional view showing the method of manufacturing the optical nonreciprocal device according to the first embodiment.

FIG. 4 is a cross-sectional view showing the method of manufacturing the optical nonreciprocal device according to the first embodiment.

FIG. 5 is a cross-sectional view showing the method of manufacturing the optical nonreciprocal device according to the first embodiment.

FIG. 6 is a cross-sectional view showing the method of manufacturing the optical nonreciprocal device according to the first embodiment.

FIG. 7 is a cross-sectional view showing ferromagnet magnetization method 1 in the first embodiment.

FIG. 8 is a cross-sectional view showing ferromagnet magnetization method 2 in the first embodiment.

FIG. 9 is a cross-sectional view showing ferromagnet magnetization method 3 in the first embodiment.

FIG. 10 is a cross-sectional view showing ferromagnet magnetization method 4 in the first embodiment.

FIG. 11 is a cross-sectional view showing ferromagnet magnetization method 5 in the first embodiment.

FIG. 12 is a cross-sectional view showing ferromagnet magnetization method 6 in the first embodiment.

FIG. 13 is a graph showing extinction coefficient α relative to gap D1 in a simulation.

FIG. 14 is a graph showing α/α_{dm} relative to gap D1 in the simulation.

FIG. 15 is a graph showing normalized light intensity relative to the number of trials in an experiment and a histogram of the normalized intensity.

FIG. 16 is a plan view of an optical circuit according to a second embodiment.

FIG. 17 is a plan view of an optical circuit in variation 1 of the second embodiment.

FIG. 18 is a plan view of an optical circuit according to a third embodiment.

FIG. 19 is a cross-sectional view taken along line XIX-XIX in FIG. 18.

FIG. 20 is a cross-sectional view taken along line XX-XX in FIG. 18.

FIG. 21 is a cross-sectional view taken along line XXI-XXI in FIG. 18.

FIG. 22 is a cross-sectional view taken along line XXII-XXII in FIG. 18.

FIG. 23 is a plan view of an optical circuit in variation 1 of the third embodiment.

FIG. 24 is a plan view of an optical circuit in variation 2 of the third embodiment.

### DETAILED DESCRIPTION

Certain embodiments of the present disclosure will be explained in detail below with reference to the drawings. The embodiments described below are examples provided to give shape to the technical ideas of the present invention and are not intended to limit the present invention to the constituent elements and the numerical values described. The same constituent elements and parts are denoted by the same numerical references in the drawings in order to omit redundant description as appropriate. The sizes of and positional relationships between the members in each drawing might be exaggerated to make the invention easily understood.

### First Embodiment

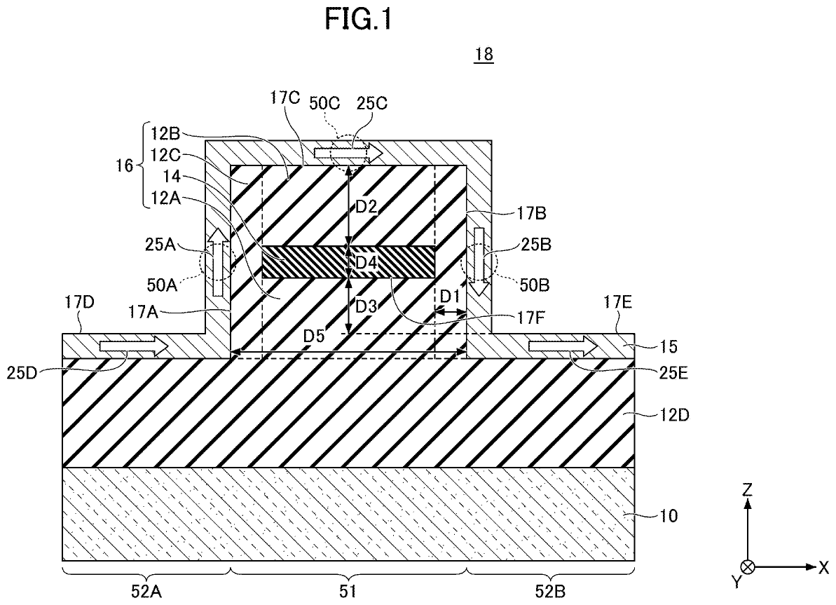

FIG. 1 is a cross-sectional view of an optical nonreciprocal device according to a first embodiment. The stacking direction of the first clad 12A, the core 14, and the second clad 12B is designated as Z direction, and the optical axis direction of the passive waveguide 16 is designated as ±Y direction. The direction orthogonal to the Y and Z directions is designated as X direction.

As shown in FIG. 1, the optical nonreciprocal device 18 according to the first embodiment includes a substrate 10, an underlayer 12D, a passive waveguide 16, and a ferromagnet 15. The underlayer 12D may be disposed on the substrate 10 to function as a clad. The substrate 10 has a first region 51 on which the passive waveguide 16 is disposed and second regions 52A, and 52B on which the passive waveguide 16 is not disposed.

The passive waveguide 16 is disposed on the underlayer 12D, and has a first clad 12A, a second clad 12B, a third clad 12C, and a core 14. The first clad 12A and the second clad 12B are stacked in the Z direction. The core 14 is disposed between the first clad 12A and the second clad 12B. The third clad 12C covers the lateral surfaces of the first clad 12A, the lateral surfaces of the core 14, and the lateral surfaces of the second clad 12B. The passive waveguide 16 has a first lateral surface 17A, a second lateral surface 17B located opposite the first lateral surface 17A, and a first upper surface 17C connecting the first lateral surface 17A and the second lateral surface 17B.

The ferromagnet 15 is disposed continuously from the area above the second region 52A to the area above the second region 52B via the area above the passive waveguide 16 on the first region 51. The ferromagnet 15 continuously covers the first lateral surface 17A, the second lateral surface 17B, and the first upper surface 17C. The ferromagnet 15 is magnetized. The magnetization directions 25C, 25D, and 25E of the ferromagnet 15 located on the first upper surface 17C and the second regions 52A and 52B are ±X direction. The magnetization direction 25A of the ferromagnet 15 disposed on the first lateral surface 17A is +Z direction. The magnetization direction 25B of the ferromagnet 15 disposed on the second lateral surface 17B is −Z direction.

The substrate 10 is, for example, a silicon, GaN, or sapphire substrate. The first clad 12A, the second clad 12B, the third clad 12C, and the underlayer 12D are insulation films, such as SiO₂, Al₂O₃, SiON, TaSiO, or the like. The core 14 is an insulation film, such as SiN, SiON, Ta₂O₃, Nb₂O₅, TiO₂, HfO₂ or the like. The refractive indices of the first clad 12A, the second clad 12B, the third clad 12C, and the underlayer 12D are smaller than the refractive index of the core 14. This confines light in the core 14 and its vicinity. The first clad 12A, the second clad 12B, the third clad 12C, and the underlayer 12D are amorphous or polycrystalline, preferably amorphous. The ferromagnet 15 is a soft magnetic material and a metal, such as permalloy which is a NiFe alloy; permendur which is a CoFe alloy; PtMnSb, MnSb, MnAs, or the like.

How the ferromagnet 15 affects light propagating in the passive waveguide 16 will be explained. The relative permittivity tensor of the ferromagnet 15 changes depending on the magnetization direction. The relative permittivity tensor of the ferromagnet magnetized in the Z direction is represented by number 1, and the relative permittivity tensor of the ferromagnet magnetized in the X direction is represented by number 2 below, in which i is the imaginary unit.

$$ε = [ \begin{matrix}{ε}_{zz} & i {ε}_{xy} ( M ) & 0 \\ - i {ε}_{xy} ( M ) & {ε}_{zz} & 0 \\ 0 & 0 & {ε}_{zz}\end{matrix} ] \qquad Number 1$$

$$ε = [ \begin{matrix}{ε}_{xx} & 0 & 0 \\ 0 & {ε}_{xx} & i {ε}_{yz} ( M ) \\ 0 & - i {ε}_{yz} ( M ) & {ε}_{xx}\end{matrix} ] \qquad Number 2$$

The nondiagonal components of the relative permittivity tensor are functions of magnetization M. The ε_{zz} and ε_{xy}(M) of number 1 and εₓₓ and ε_{yz}(M) of number 2 are complex numbers. Nonreciprocal phase shift effect is expressed by the real parts of the nondiagonal components ε_{xy}(M) and ε_{yz}(M), and nonreciprocal loss effect is expressed by the imaginary parts of the nondiagonal components ε_{xy}(M) and ε_{yz}(M). The positive and negative signs of the nondiagonal components ε_{xy}(M) and ε_{yz}(M) are reversed when switching the magnetization M into −M. When the electric field component of the light propagating in the passive waveguide 16 overlaps a properly magnetized ferromagnet 15, the light is affected by the magnetization and loses its power. The magnitude of the loss changes in accordance with the magnitude of the imaginary parts of the nondiagonal components ε_{xy}(M) and ε_{yz}(M).

When the light propagating in the passive waveguide 16 is in a TE (transverse electric) mode, the electric field component overlapping the ferromagnet 15 in the ranges 50A and 50B feels nonreciprocity. In other words, the relative permittivity tensor of number 1 acts on the TE mode light. For example, when light propagates in the +Y direction in FIG. 1, in a TE mode, the magnetization direction 25A works to increase optical loss in the range 50A, and the magnetization direction 25B works to increase optical loss in the range 50B. When the propagation direction of light is reversed (i.e., −Y direction), the magnetization direction 25A works to decrease optical loss in the range 50A, and the magnetization direction 25B works to decrease optical loss in the range 50B. As such, optical loss differs depending on the propagation direction of light in the passive waveguide 16. In this manner, it functions as an optical nonreciprocal device.

When the light propagating in the passive waveguide 16 is in a TM (transverse magnetic) mode, the electric field component overlapping the ferromagnet 15 in the range 50C feels nonreciprocity. In other words, the relative permittivity tensor of number 2 acts on the TM mode light. For example, when light propagates in the +Y direction in FIG. 1, in a TM mode, the magnetization direction 25C works to increase optical loss in the range 50C. When the propagation direction of light is reversed, the magnetization direction 25C works to decrease optical loss in the range 50C. As such, optical loss differs depending on the propagation direction of light in the passive waveguide 16. In this manner, it functions as an optical nonreciprocal device.

In the case in which the ferromagnet 15 is disposed on only one of the first lateral surface 17A, the second lateral surface 17B, and the first upper surface 17C of the passive waveguide 16, the magnetic field lines leak from the end surfaces of the ferromagnet 15 into a space thereby reduces the magnitude of magnetization.

In the first embodiment, the ferromagnet 15 continuously covers the first lateral surface 17A, the second lateral surface 17B, and the first upper surface 17C of the passive waveguide 16. This can suppress leakage of the magnetic field lines from the end surfaces of the ferromagnet 15 into a space, and thus magnetization can be strengthened. In an XZ cross section (cross section perpendicular to the optical axis of the passive waveguide 16), the core 14, a portion of the ferromagnet 15 covering the first lateral surface 17A, and a portion of the ferromagnet 15 covering the second lateral surface 17B overlap in the X direction (direction perpendicular to the Z direction). In other words, relative to the position Z of the core 14, portions of the ferromagnet 15 are located in the +X and −X directions of the core 14. This can allow the electric field component of the light propagating in the passive waveguide 16 to overlap the ferromagnet 15 in the ranges 50A and 50B, and thus the optical nonreciprocity can be strengthened. Employing a passive waveguide 16 as an optical waveguide can allow the lower end of the ridge to be positioned lower than the lower surface 17F of the core 14 as compared to an active waveguide having an active layer as in the case of the optical waveguide in Patent Literature 1. This is because there is no need to take into consideration the formation of a current injection leak path or potential damage to the active layer during the formation of a ridge. The passive waveguide 16 with the lower end of the ridge being positioned lower than the lower surface 17F of the core 14 can have relatively strong lateral light confinement effect and reduce losses when the waveguide is bent. Accordingly, losses can be reduced by applying the passive waveguide 16 to a ring resonator such as in the cases of the second and third embodiments described later.

The passive waveguide 16 preferably includes a second clad 12B and a third clad 12C. The ferromagnet 15 covers the lateral surfaces of the third clad 12C and the upper surface of the second clad 12B. This can reduce the absorption of light by the ferromagnet 15, and thus light losses can be reduced. In a TE mode, the electric fields in the ranges 50A and 50B can be set to desirable sizes. In a TM mode, the electric field in the range 50C can be set to a desirable size. This can strengthen optical nonreciprocity while reducing light losses.

In a TE mode, from the standpoint of strengthening optical nonreciprocity, the thickness of the third clad 12C in the X direction (direction perpendicular to the Z direction in a XZ cross section perpendicular to the optical axis of the passive waveguide 16), i.e., the shortest distance from a lateral surface of the core 14 to the ferromagnet 15, referred to as gap D1 in the present specification, is preferably twice the value λ/n_{eff} or smaller, more preferably 0.5 times or smaller. The value λ/n_{eff} is obtained by dividing the wavelength λ σf light by the effective refractive index n_{eff} of the waveguide mode. In a TM mode, from the standpoint of strengthening optical nonreciprocity, the thickness of the second clad 12B (gap D2) in the Z direction (direction perpendicular to the X direction in a XZ cross section perpendicular to the optical axis of the passive waveguide 16) is preferably five times the value λ/n_{eff} obtained by dividing the wavelength λ of light by the effective refractive index n_{eff} of the waveguide mode or smaller, more preferably 2 times or smaller. From the standpoint of reducing light losses, the thickness of the third clad 12C (gap D1) is preferably at least 0.1 times the value λ/n_{eff} obtained by dividing the wavelength λ of light by the effective refractive index n_{eff} of the waveguide mode.

In an XZ cross section, the second upper surfaces 17D and 17E of the ferromagnet 15 located on the second regions 52A and 52B are positioned closer to the substrate 10 than the lower surface 17F of the core 14. In other words, the distance from the second upper surfaces 17D and 17E to the lower surface 17F in the Z direction (gap D3) is positive. This makes the magnetization directions 25A and 25B of the ferromagnet on both sides of the core 14 opposite directions, and, for a TE mode, the electric field interacts with the ferromagnet in both ranges 50A and 50B, thus strengthening the nonreciprocity. The gap D3 is preferably about the thickness of the second clad 12B (gap D2).

For a TE mode, the gap D1 may be, for example, 10 nm to 500 nm. For a TM mode, the gap D1 may be 500 nm or larger. This is because the portions where the ferromagnet 15 interacts with light differ depending on the mode. For a TM mode, the gap D2 may be, for example, 10 nm to 500 nm. For a TE mode, the gap D2 may be 500 nm or larger. The gap D3 may be, for example, 10 nm to 500 nm, but may be 10 nm or smaller for a TM mode. The thickness D4 of the core 14 may be, for example, 10 nm to 1000 nm. The core 14 preferably has a thickness D4 that satisfies single mode conditions with respect to the wavelength of the light propagating in the passive waveguide16.

The ferromagnet 15 is at least one selected from the group consisting of permalloy, permendur, PtMnSb, MnBi, MnSb, and MnAs. The ferromagnet 15 can then be easily made because they are metal. The thickness of the metal film is preferably larger than the skin depth of the light waveguided in the passive waveguide 16. The skin depth is defined by a reciprocal of attenuation constant, (2/(μωσ))^{1/2}, in which μ is the magnetic permeability of the ferromagnet 15, ω is the angular frequency of light waveguided in the passive waveguide 16, and σ is the electrical conductivity of the ferromagnet 15. The thickness of the ferromagnet 15 may be, for example, in a range of 5 nm to 300 nm or 10 nm to 100 nm.

The passive waveguide 16 is formed of an amorphous material. This can reduce losses in the case of bending the waveguide, as compared to the case of forming the passive waveguide 16 by using a monocrystalline or polycrystalline material.

### Method of Manufacturing First Embodiment

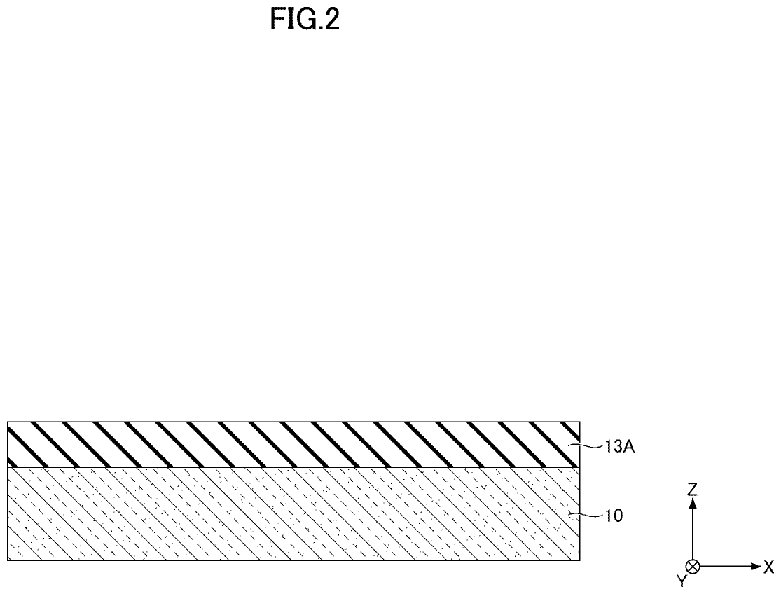

FIG. 2 to FIG. 6 are cross-sectional views showing an example of method of manufacturing an optical nonreciprocal device according to the first embodiment. As shown in FIG. 2, a first layer 13A is formed on a substrate 10. The substrate 10 is, for example, a silicon substrate, and the first layer 13A is, for example, a SiO₂ film of 4000 nm in thickness. The first layer 13A is formed, for example, by thermal oxidation of the surface of the substrate 10.

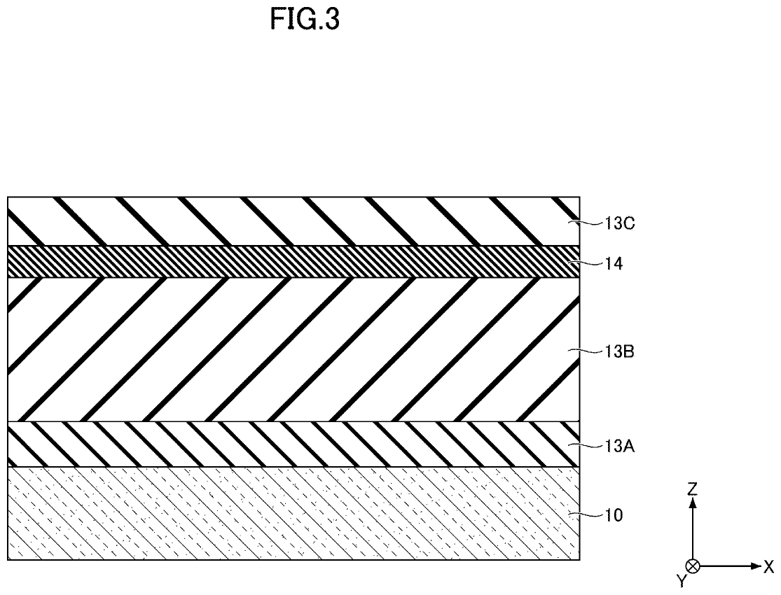

Then as shown in FIG. 3, a second layer 13B, a core 14, and a third layer 13C are formed on the first layer 13A. The second layer 13B is, for example, a SiON film of 750 nm in thickness, the core 14 is, for example, a Ta₂O₃ film of 50 nm in thickness, and the third layer 13C is, for example, a SiO₂ film of 500 nm in thickness. The second layer 13B, the core 14, and the third layer 13C are formed by sputtering, for example. The first layer 13A and the third layer 13C may be formed of the same material. This can control the refractive index in the stacking direction, making it easy to confine light in the stacking direction of the optical nonreciprocal device 18 to be produced.

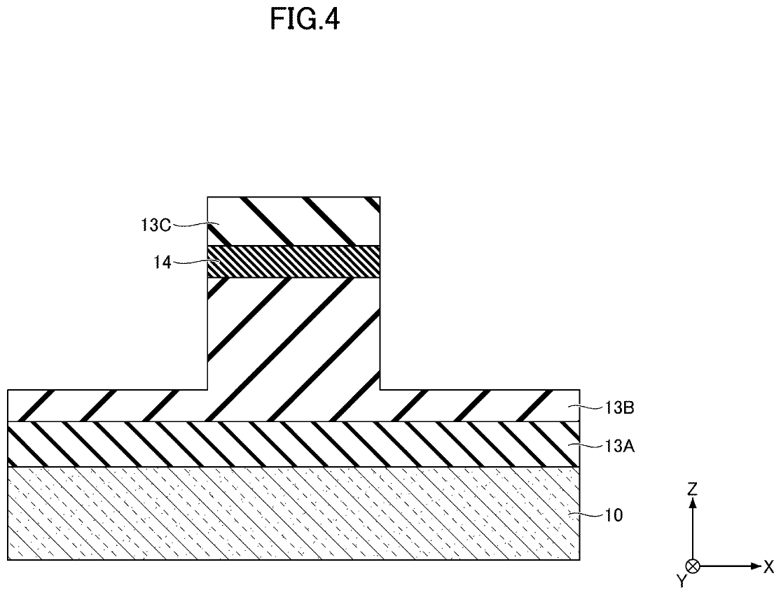

Then as shown in FIG. 4, the third layer 13C, the core 14, and the second layer 13B are etched to a desired shape. A portion of the second layer 13B remains across the first layer in the Z direction. Etching is performed via a patterned mask. For example, electron beam lithography, photolithography, or dry etching is used to pattern the mask.

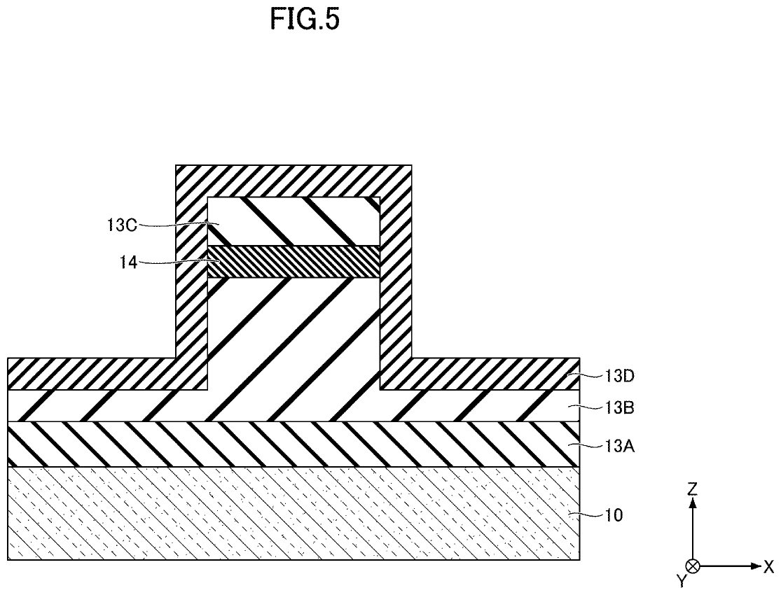

Then as shown in FIG. 5, a fourth layer 13D is formed on the second layer 13B to cover the core 14 and the third layer 13C. The fourth layer 13D is, for example, a SiO₂ film of 200 nm in thickness. The fourth layer 13D is formed by sputtering, for example.

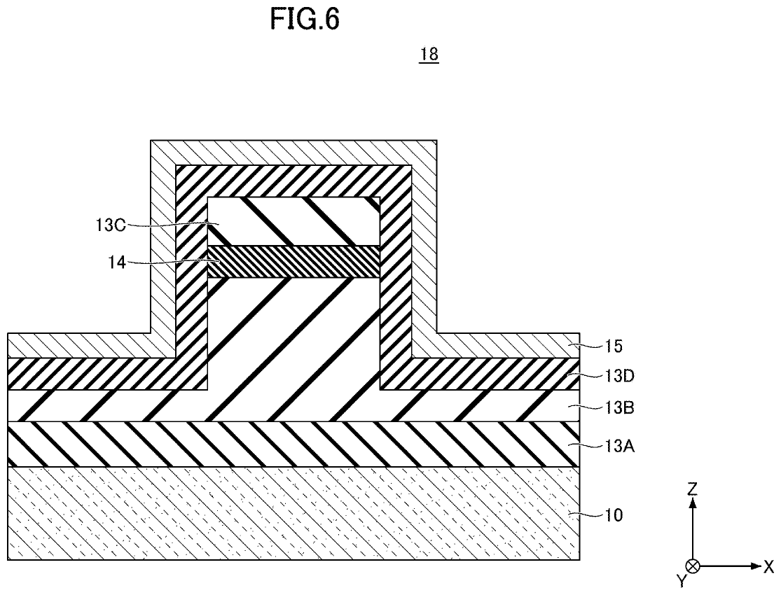

Then as shown in FIG. 6, a ferromagnet 15 is formed on the fourth layer13D. The ferromagnet 15 is, for example, a permalloy film of 200 nm in thickness. The ferromagnet 15 is formed by sputtering, for example. In this manner, the first clad 12A in FIG. 1 is formed of a portion of the second layer 13B. The second clad 12B in FIG. 1 is formed of a portion of the third layer 13C and a portion of the fourth layer 13D. The third clad 12C in FIG. 1 is formed of a portion of the fourth layer 13D. The underlayer 12D in FIG. 1 is formed of the first layer 13A, a portion of the second layer 13B, and a portion of the fourth layer 13D. An optical nonreciprocal device 18 according to the first embodiment is produced as described above. Because the fourth layer 13D is also formed on the third layer 13C, the magnitude relation between the gap D1 and the gap D2 in FIG. 1 can be adjusted. If the gap D1 is smaller than the gap D2, the device can be mainly operated for TE mode light. If the gap D1 is larger than the gap D, the device can be mainly operated for TM mode light. Accordingly, the optical nonreciprocal device can work on either TE or TM mode.

In the manufacturing method in the first embodiment described above, using sputtering to form the second layer 13B, the third layer 13C, the fourth layer 13D, and the core 14 allows the second layer 13B, the third layer 13C, the fourth layer 13D, and the core 14 to be amorphous materials. Moreover, employing sputtering to form the ferromagnet 15 can form the ferromagnet 15 along the first lateral surface 17A, the second lateral surface 17B, the first upper surface 17C, continuous with the second upper surfaces 17D and 17E.

### Ferromagnet Magnetization Method

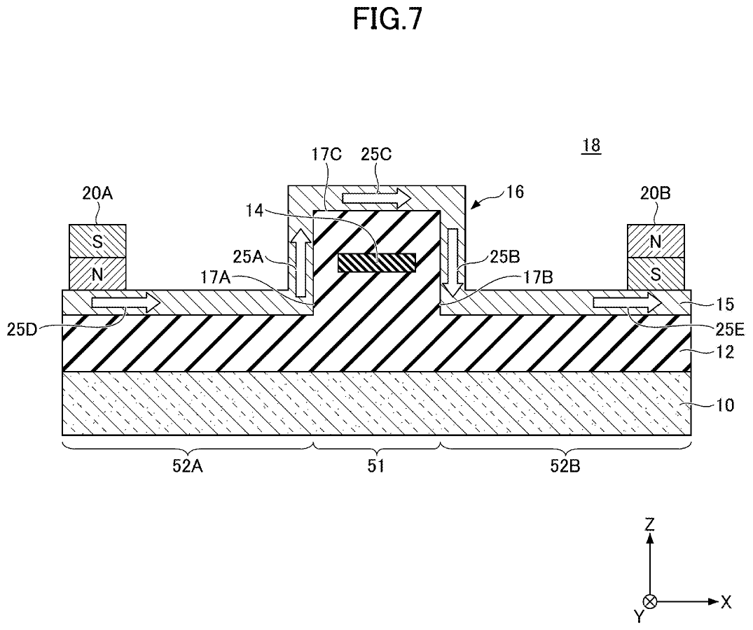

Ferromagnet magnetization methods will be explained. FIG. 7 is a cross-sectional view showing ferromagnet magnetization method 1 in the first embodiment. As shown in FIG. 7, in the magnetization method 1, a magnet 20A is placed on the ferromagnet 15 located on the second region 52A. The N pole of the magnet 20A is disposed on the ferromagnet 15. A magnet 20B is placed on the ferromagnet 15 located on the second region 52B. The S pole of the magnet 20B is disposed on the ferromagnet 15. This allows magnetic field lines to extend from the magnet 20A to the magnet 20B. Thus, the ferromagnet 15 is magnetized in magnetization directions 25A to 25E. As described above, the ferromagnet 15 continuously covers the first lateral surface 17A, the second lateral surface17B, and the first upper surface 17C of the passive waveguide 16. This confines the magnetic field lines in the ferromagnet 15, and the magnetization directions of the ferromagnet 15 connect the magnet 20A and the magnet 20B, i.e., they are oriented in magnetization directions 25D, 25A, 25C, 25B, and 25E, as shown in FIG. 7.

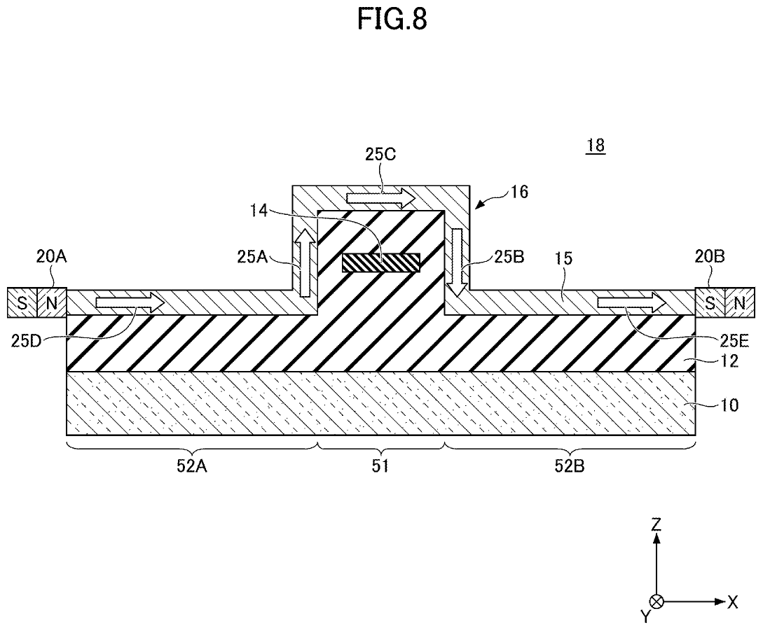

FIG. 8 is a cross-sectional view showing ferromagnet magnetization method 2 in the first embodiment. As shown in FIG. 8, in the magnetization method 2, the N pole of the magnet 20A is disposed on the end surface of the ferromagnet 15 in the second region 52A. The S pole of the magnet 20B is disposed on the end surface of the ferromagnet 15 in the second region 52B. This magnetizes the ferromagnet 15 in magnetization directions 25A to 25E.

As described above, the ferromagnet 15 is a soft magnetic material that is easy to magnetize. In the magnetization methods 1 and 2, the magnets 20A and 20B are preferably permanent magnets. This allows for continuous magnetization of the ferromagnet 15 simply by placing the magnets 20A and 20B, thereby eliminating the need for supplying energy from the outside to maintain the magnetization of the ferromagnet 15.

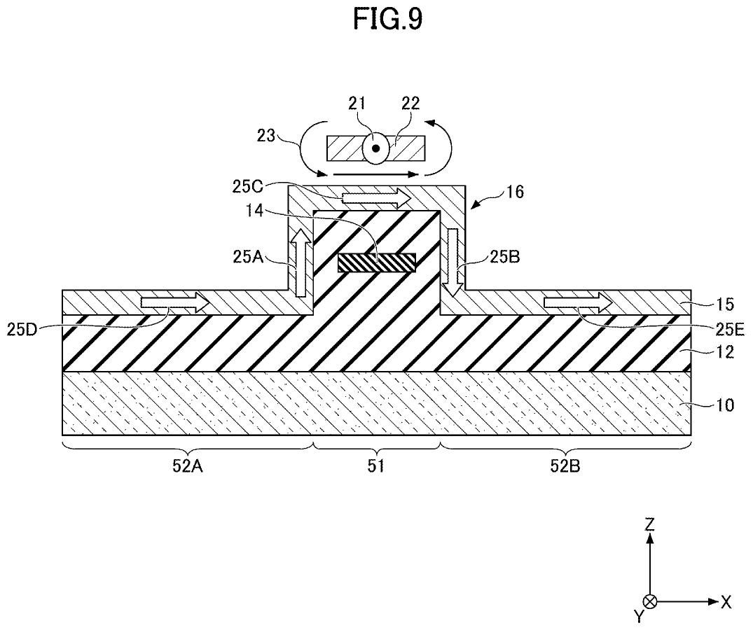

FIG. 9 is a cross-sectional view showing ferromagnet magnetization method 3 in the first embodiment. As shown in FIG. 9, in the magnetization method 3, a conducting pad 22 is disposed above the ferromagnet 15 in the first region 51. An electric current is supplied to the conducting pad 22 such that the current direction 21 is −Y direction. This creates a magnetic field around the conducting pad 22. The magnetic field lines 23 go around counterclockwise. This orients the magnetic field lines in the ferromagnet 15 on the passive waveguide 16 in the first region 51 in +X direction, making the magnetization direction 25C +X direction. Subsequently, the entire ferromagnet 15 is magnetized. Because the magnetic field made by the current intensifies in proportion with the magnitude of the current, increasing the magnitude of the current above a certain magnitude can magnetize the ferromagnet in the second regions 52A and 52B also, which are distant from the conducting pad 22. The entire ferromagnet 15 may be magnetized in this manner. An insulation film, which is a nonmagnetic material, may be disposed between the ferromagnet 15 and the conducting pad 22 for supporting the conducting pad 22.

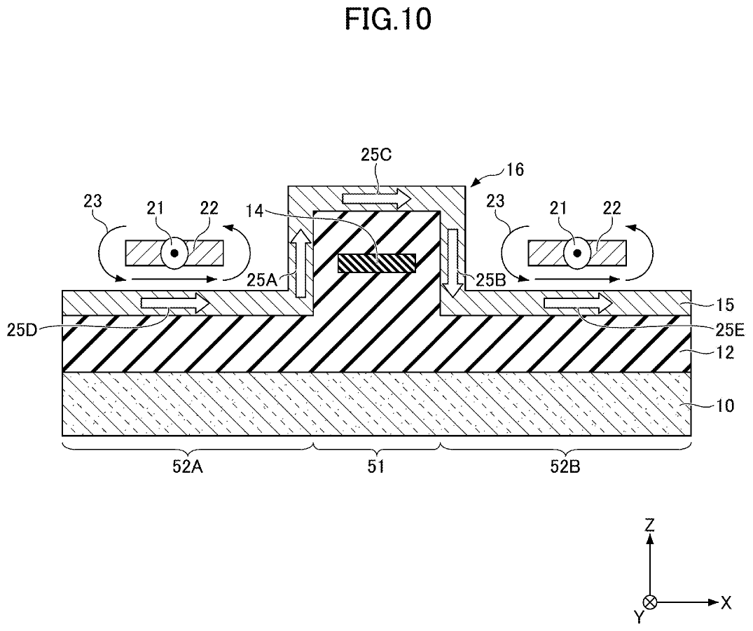

FIG. 10 is a cross-sectional view showing ferromagnet magnetization method 4 in the first embodiment. As shown in FIG. 10, in the magnetization method 4, conducting pads 22 are disposed above the ferromagnet 15 in the second regions 52A and 52B. An electric current is supplied to the conducting pads 22 such that the current direction 21 of the conducting pards 22 is −Y direction. This makes the magnetization directions 25A and 25B on the lateral surfaces of the passive waveguide 16 +Z and −Z directions, respectively, and the magnetization directions 25D and 25E in the ferromagnet 15 on the passive waveguide 16 in the second regions 52A and 52B +X direction. The number of conducting pads 22 positioned above the ferromagnet 15 may be three or more. An insulation film, which is a nonmagnetic material, may be disposed between the ferromagnet 15 and the conducting pads 22 for supporting the conducting pads 22.

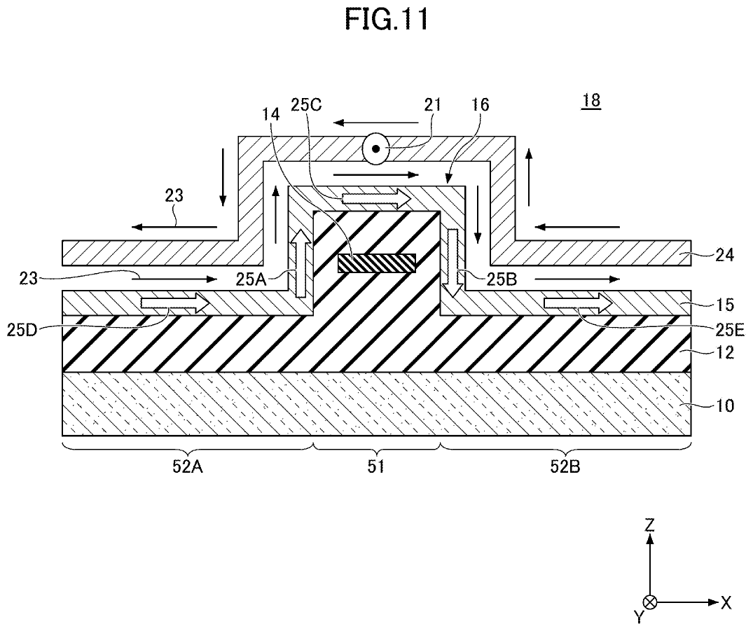

FIG. 11 is a cross-sectional view showing ferromagnet magnetization method 5 in the first embodiment. As shown in FIG. 11, in the magnetization method 5, a conducting pad 24 is positioned above the ferromagnet 15 in the first region 51 and the second regions 52A and 52B. An electric current is supplied to the conducting pad 24 such that the current direction 21 is −Y direction. This magnetizes such that the magnetization direction 25A is +Z direction, the magnetization direction 25B −Z direction, and the magnetization directions 25C, 25D, and 25E +X direction. An insulation film, which is a nonmagnetic material, may be disposed between the ferromagnet 15 and the conducting pad 24 for supporting the conducting pad 24.

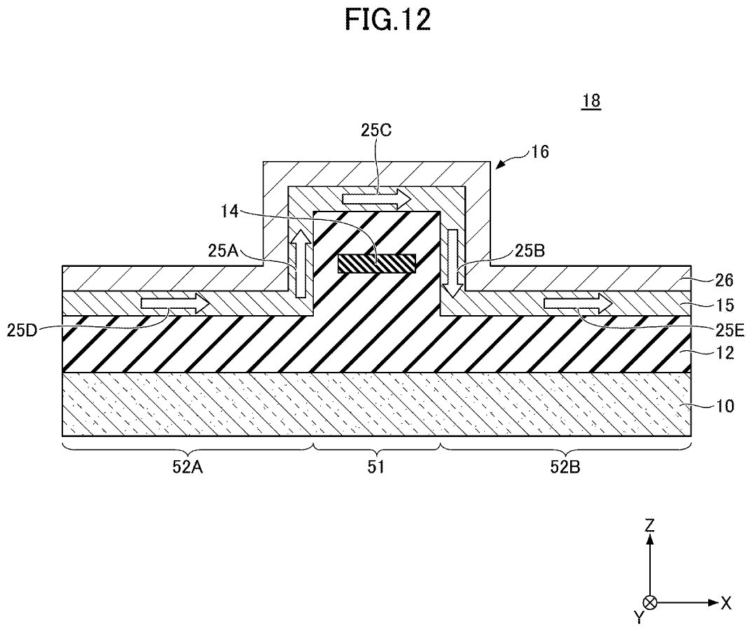

FIG. 12 is a cross-sectional view showing ferromagnet magnetization method 6 in the first embodiment. As shown in FIG. 12, in the magnetization method 6, an antiferromagnetic film 26 is disposed on the ferromagnet 15 in the first region 51 and the second regions 52A and 52B. After magnetizing the ferromagnet 15 by using any one of the magnetization methods 1 to 5, the magnetization directions 25A to 25E are fixed by the exchange bias at the interface between the antiferromagnetic film 26 and the ferromagnet 15. This eliminates the need for keeping the magnets 20A and 20B in place as in the case of magnetization method 1 or 2. Furthermore, there is no need to keep supplying an electric current to the conducting pads 22 (or 24) as in the cases of magnetization methods 3 to 5. The antiferromagnetic film 26 may be, for example, manganese oxide (MnO), nickel oxide (NiO), or Mn₃Sn.

### Simulation

The magnitude of nonreciprocity in the first embodiment was simulated as a function of the gap D1. The gap D2 in FIG. 1 was set to (500+D1×2) nm, the gap D3 was set to 50 nm, the thickness D4 of the core 14 was set to 50 nm, and the width D5 of the passive waveguide 16 was set to 2000 nm. Ta₂O₅ was used as the material for the core 14, SiON for the first clad 12A and the underlayer 12D, SiO₂ for the second clad 12B and the third clad 12C, and permalloy for the ferromagnet 15. Using Tikuisis et al., Materials and Design 114, 31 (2017) as a reference, the diagonal component in number 1 was set to εₓₓ=−6+12i and the nondiagonal component was set to ε_{xy}=−0.1+0.2i at a wavelength of 460 nm in which i is the imaginary unit. The per-unit-distance extinction coefficient α [1/cm] with respect to the 460 nm wavelength light was simulated. Extinction coefficient α₊ when TE mode light propagates in the passive waveguide 16 in the forward direction, extinction coefficient α₋ when TE mode light propagates in the passive waveguide 16 in the reverse direction, and extinction coefficient α_{dm} of the passive waveguide 16 when the ferromagnet 15 is demagnetized were calculated.

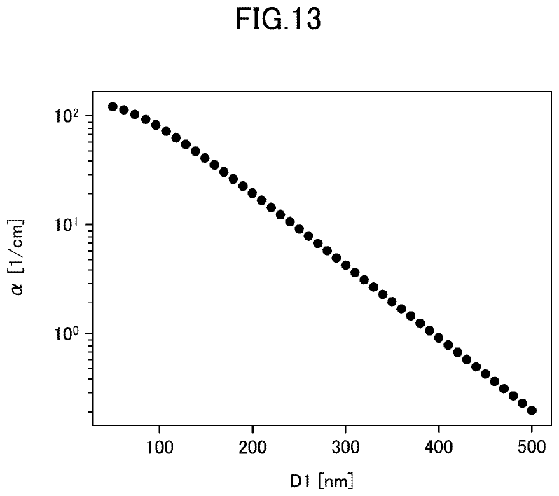

FIG. 13 is a graph showing extinction coefficient α relative to gap D1 in the simulation. Because the extinction coefficients α₊, α₋, and α_{dm} are practically the same values in the scale shown in FIG. 13, the results are shown by using one extinction coefficient α. As shown in FIG. 13, extinction coefficient α increases as the gap D1 decreases. This is because the loss increases as the gap D1 decreases which increases the electric field component in a TE mode in the ferromagnet 15.

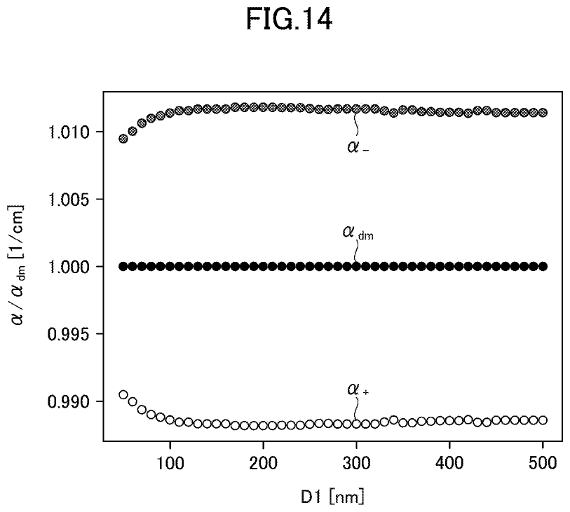

FIG. 14 is a graph showing α/α_{dm} relative to gap D1 in the simulation. The α/α_{dm} represents extinction coefficients α₊, α₋, and α_{dm} relative to α_{dm}. As shown in FIG. 14, α_{dm}/α_{dm} is 1, α⁻/α_{dm} is greater than 1.000, about 1.01, and α₊/α_{dm} is smaller than 1.000, about 0.99. This indicates that the loss of light propagating in the reverse direction in the passive waveguide 16 is larger than the loss of light propagating in the forward direction in the passive waveguide 16.

### Experiment

An optical nonreciprocal device in which the gap D1 was 100 nm and the other conditions were the same as those used in the simulation was fabricated. The ferromagnet 15 was magnetized by using the magnetization method 1 shown in FIG. 7. The intensity of light propagating through the passive waveguide 16 was measured by alternating the magnets 20A and 20B.

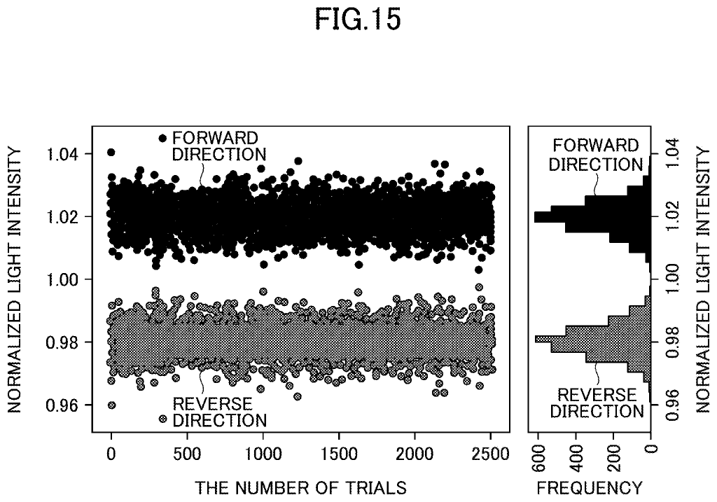

FIG. 15 shows a graph showing normalized light intensity relative to the number of trials in the experiment, and a histogram of the normalized light intensity. The horizontal axis of the graph on the left represents the number of trials, and the vertical axis represents the light intensity normalized by using the light intensity when the ferromagnet 15 is not magnetized. The label, forward direction, represents normalized light intensity of the light passing through the passive waveguide 16 in the forward direction, and the label, reverse direction, represents normalized light intensity of the light passing through the passive waveguide in the reverse direction. In the experiment, the electromagnet current direction was changed to change the orientation of the magnetic field. Thus, even if the light is propagated in one direction relative to the passive waveguide 16, forward and reverse propagation are essentially achieved by changing the magnetic field orientation. The graph on the right is a histogram of the normalized light intensity in forward and reverse directions.

As shown in FIG. 15, the forward direction normalized light intensity is about 1.02 and the reverse direction normalized light intensity is about 0.98. As a result of the simulation and the experiment, the first embodiment was found to function as an optical nonreciprocal device.

### Second Embodiment

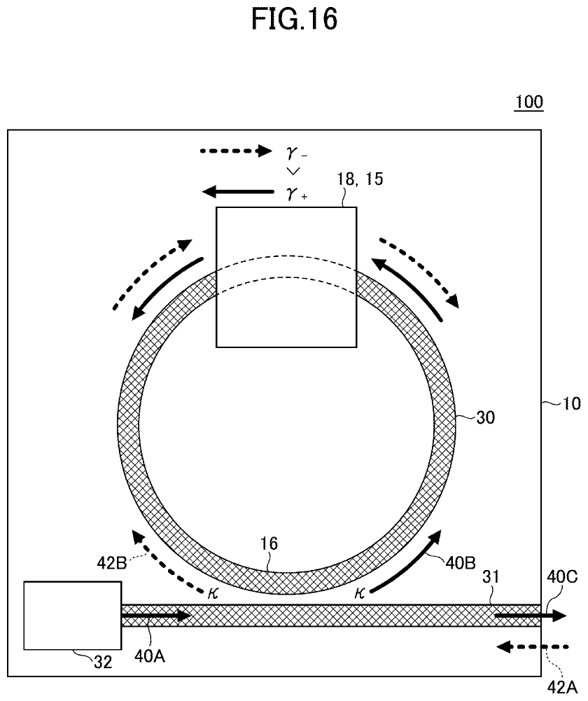

A second embodiment is an example of optical circuit which uses an optical nonreciprocal device of the first embodiment. FIG. 16 is a plan view of the optical circuit according to the second embodiment. As shown in FIG. 16, the optical circuit 100 of the second embodiment includes an optical nonreciprocal device 18, a ring resonator 30, an optical waveguide 31, and a semiconductor laser element 32. The ring resonator 30, the optical waveguide 31, and the semiconductor laser element 32 are disposed on a substrate 10. The optical waveguide 31 is a straight waveguide and optically coupled to the semiconductor laser element 32. The ring resonator 30 has a passive waveguide 16 provided in a ring shape. The ring resonator 30 is optically coupled to the optical waveguide 31. The optical nonreciprocal device 18 is positioned at a portion of the ring resonator 30. In the optical nonreciprocal device 18, the ferromagnet 15 is positioned to cover the passive waveguide 16.

The light 40A emitted by the semiconductor laser element 32 enters one end of the optical waveguide 31 and propagates in the optical waveguide 31. The coupling rate of the optical waveguide 31 and the ring resonator 30 is κ. A portion of the light 40A couples to the ring resonator 30 and propagates in the ring resonator 30 counterclockwise as light 40B. The loss rate γ₊ of the light 40B of the optical nonreciprocal device 18 is smaller than the coupling rate κ. Under this overcoupling condition, the light 40B is coupled to the optical waveguide 31 without being completely absorbed in the ring resonator 30 to exit the other end of the optical waveguide 31 as light 40C.

A portion of the return light 42A entering the other end of the optical waveguide 31 back into the optical waveguide 31 couples to the ring resonator 30 and propagates in the ring resonator 30 clockwise as light 42B. The loss rate γ₋ of the light 42B of the optical nonreciprocal device 18 is higher than the loss rate γ₊, and is the same as the coupling rate κ. Under this critical coupling condition, the light 42B is completely absorbed in the ring resonator 30. Thus, the return light 42A does not reach the semiconductor laser element 32. As such, the ring resonator 30 having the optical nonreciprocal device 18 functions as an optical isolator. The critical coupling condition does not necessarily have to be satisfied, and the loss rate γ₋ of the light 42B of the optical nonreciprocal device 18 has only to be higher than the loss rate γ₊, and about the same as the coupling rate κ. In other words, it is fine if the return light 42A is sufficiently reduced. For example, the difference between the loss rate γ₋ and the coupling rate κ may be considered as about the same if it can reduce the light intensity by 10 dB or more, preferably 30 dB or more, as compared to that before the return light 42A couples to the passive waveguide 16.

### Variation 1 of the Second Embodiment

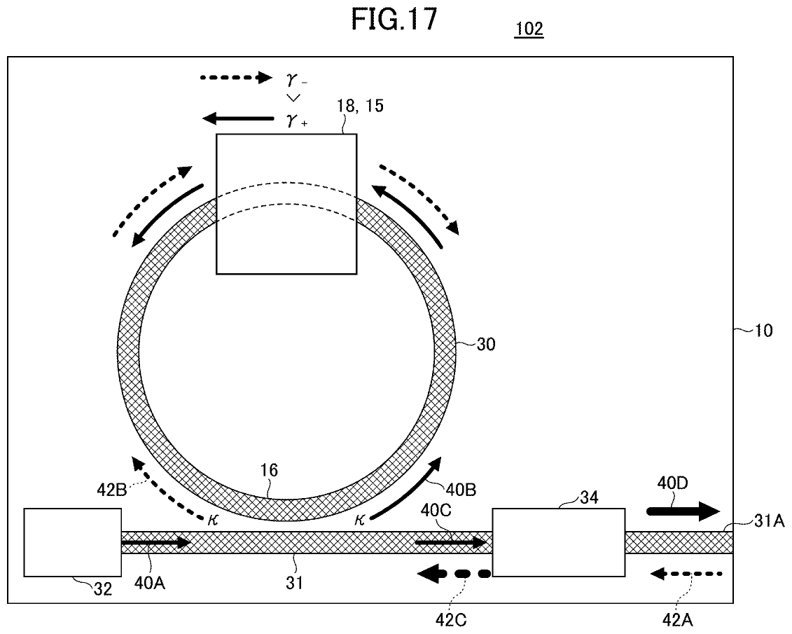

FIG. 17 is a plan view of an optical circuit according to Variation 1 of the second embodiment. As shown in FIG. 17, the optical circuit 102 of Variation 1 of the second embodiment includes an optical waveguide 31A and an optical amplifier 34 in addition to the optical nonreciprocal device 18, the ring resonator 30, the optical waveguide 31, and the semiconductor laser element 32.

The optical nonreciprocal device 18 according to the first and second embodiments utilizes the propagation loss difference between the forward and reverse directions. In other words, a loss occurs even in the forward direction. Accordingly, the forward direction light is preferably amplified before being extracted. On the other hand, a portion of the amplified light becomes return light. However, the optical nonreciprocal device 18 can reduce the return light.

The optical waveguide 31A and the optical amplifier 34 are disposed on the substrate 10. The optical waveguide 31A is a straight waveguide and optically coupled to the optical amplifier 34. The optical waveguide 31 connects the semiconductor laser element 32 and the optical amplifier 34. The ring resonator 30 optically couples to the optical waveguide 31A. The optical amplifier 34 amplifies the light 40C and outputs the amplified light 40D to the optical waveguide 31A. The amplified light 40D exits the other end of the optical waveguide 31A.

The return light 42A enters that end of the optical waveguide 31A. The optical amplifier 34 amplifies the light 42A and outputs the amplified light 42C to the optical waveguide 31. The light 40C couples to the ring resonator 30 under critical coupling conditions. Thus, the light 42B that propagates in the ring resonator 30 is completely absorbed. Accordingly, similar to the optical circuit 100 of the second embodiment, the light 42C never reaches the semiconductor laser element 32, or the light 42C is adequately reduced.

According to Variation 1 of the second embodiment, the ring resonator 30 including an optical nonreciprocal device 18 is optically coupled to the optical waveguide 31 that links the semiconductor laser element 32 and the optical amplifier 34. This allows the light 40D amplified by the optical amplifier 34 to be output. The light 42C amplified by the optical amplifier 34 is absorbed by the optical nonreciprocal device 18 of the ring resonator 30. It can increase the laser light output while reducing the return light as described above.

### Third Embodiment

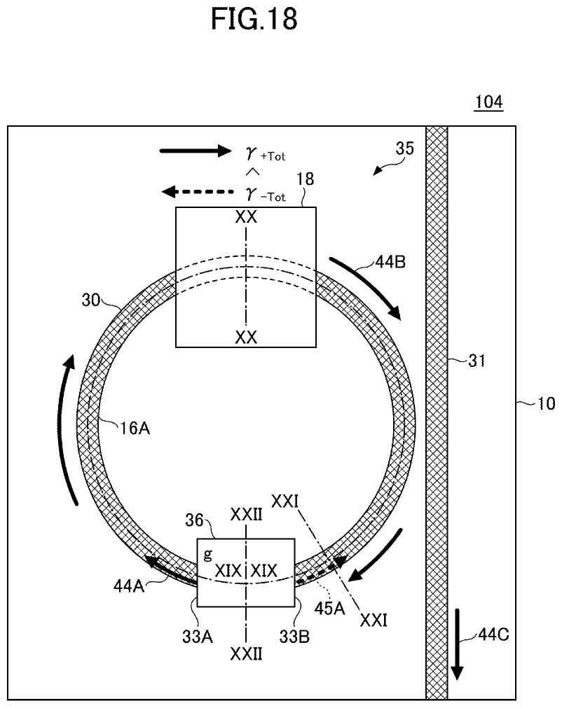

A third embodiment is an example of an optical circuit using an optical nonreciprocal device of the first embodiment, and is a ring laser example. FIG. 18 is a plan view of the optical circuit according to the third embodiment. As shown in FIG. 18, the optical circuit 104 according to the third embodiment includes a ring laser 35 and an optical waveguide 31. The ring laser 35 includes an optical nonreciprocal device 18, a ring resonator 30, and a semiconductor layer element part 36. The ring resonator 30, the optical waveguide 31, and the semiconductor laser element part 36 are disposed on a substrate 10. The optical nonreciprocal device 18 and the semiconductor laser element part 36 are disposed on a portion of the ring resonator 30. The semiconductor laser element part 36 has a first end surface 33A and a second end surface 33B located opposite the first end surface 33A. In the ring resonator 30, the optical waveguide 16A is provided in a ring shape. The optical waveguide 16A links the first end surface 33A and the second end surface 33B. The ring resonator 30 is optically coupled to the optical waveguide 31 which is a straight waveguide.

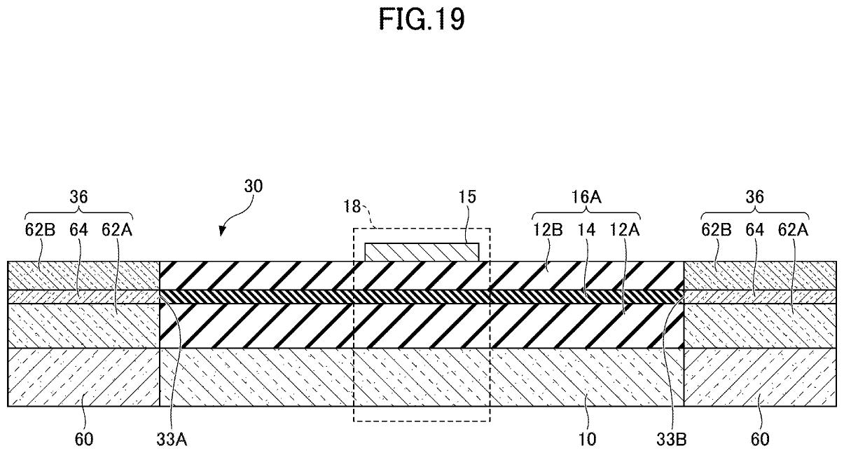

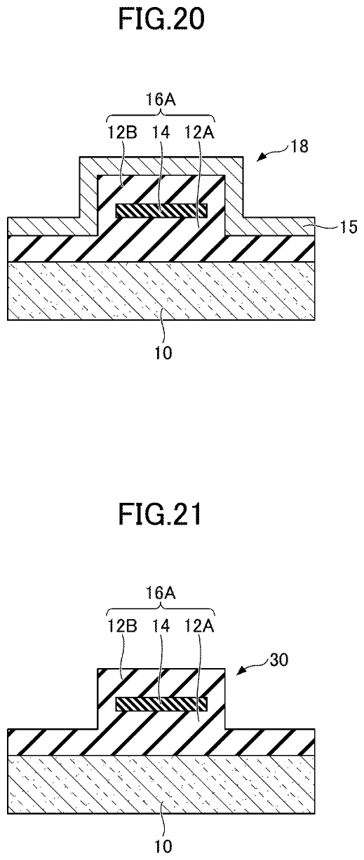

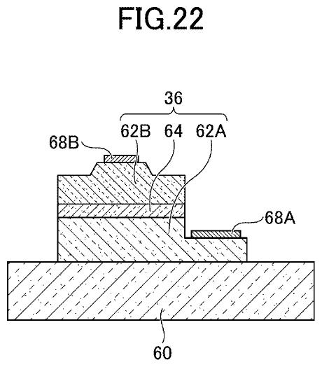

FIG. 19 is a cross-sectional view taken along line XIX-XIX in FIG. 18, FIG. 20 is a cross-sectional view taken along line XX-XX in FIG. 18, FIG. 21 is a cross-sectional view taken along line XXI-XXI in FIG. 18, and FIG. 22 is a cross-sectional view taken along line XXII-XXII in FIG. 18. FIG. 19 is a cross section along the optical axis of the ring resonator 30, and the right end part and the left end part in FIG. 19 are of the same semiconductor laser element part 36.

As shown in FIG. 19 and FIG. 22, the semiconductor laser element part 36 includes a substrate 60, clads 62A and 62B, and a core 64. The clads 62A and 62B are disposed on the substrate 60. The core 64 is disposed between the clads 62A and 62B. The n-side electrode 68A is electrically connected to the clad 62A. The p-side electrode 68B is electrically connected to the clad 62B. The clads 62A and 62B and the core 64 include, for example, GaN, AlN, InN, or a mixed crystal of these, such as AlGaN, InGaN, AlInN, or AlInGaN. The refractive index of the core 64 is higher than those of the clads 62A and 62B. This confines light in the core 64 and its vicinity. The substrate 60 may be one that is the same as or different from the substrate 10.

The ring resonator 30 has an optical waveguide 16A disposed on the substrate 10. The optical waveguide 16A includes a first clad 12A, a second clad 12B, and a core 14. The core 14 is disposed between the first clad 12A and the second clad 12B. The optical nonreciprocal device 18 has a passive waveguide 16 and a ferromagnet 15. The ferromagnet 15 is disposed on the upper surface and the lateral surfaces of the optical waveguide 16A. The structure of the ferromagnet 15 is the same as that in the first embodiment for which the description is omitted.

As shown in FIG. 19, the first end surface 33A and the second end surface 33B of the semiconductor laser element part 36 are optically coupled to the optical waveguide 16A. The cores 64 and 14 oppose one another. The optical waveguide 16A and the semiconductor laser element part 36 form a closed loop.

As shown in FIG. 20 and FIG. 21, the ferromagnet 15 is provided on the portion of the optical waveguide 16A that functions as the optical nonreciprocal device 18, and not provided on the portion that does not function as the optical nonreciprocal device 18.

As shown in FIG. 18, the semiconductor laser element part 36 emits light 44A and 45A from the first end surface 33A and the second end surface 33B, respectively. The light 44A propagates in the ring resonator 30 clockwise and enters the semiconductor laser element part 36 from the second end surface 33B of the semiconductor laser element part 36. The light 45A propagates in the ring resonator 30 counterclockwise and enters the semiconductor laser element part 36 from the first end surface 33A of the semiconductor laser element part 36.

The gain rate of the semiconductor laser element part 36 is g. The forward direction of the optical nonreciprocal device 18 is the clockwise direction of the ring resonator 30. Accordingly, the counterclockwise total loss γ_{-Tot} of the ring resonator 30 is greater than the clockwise total loss γ_{+Tot} of the ring resonator 30. When the gain rate is set as g<γ_{-Tot}, because the gain rate is smaller than the loss rate for the light 45A, no counterclockwise mode laser oscillation occurs. When the gain rate g is set as g=γ_{+Tot}, clockwise mode laser oscillation occurs. The clockwise mode light 44B is emitted as laser light 44C from one end of the optical waveguide 31 optically coupled to the ring resonator 30. No laser light is emitted from the other end of the optical waveguide 31.

According to the third embodiment, the optical nonreciprocal device 18 is disposed in at least one portion of the ring resonator 30. This allows for laser oscillation either in the counterclockwise or the clockwise mode. The return light from one end of the optical waveguide 31 couples to the other mode with no laser oscillation in the ring resonator 30. Consequently, instability in the laser operation due to optical feedback can be suppressed. With reference to FIG. 18, an example was described in which laser oscillation selectively occurred in a clockwise mode while reducing the counterclockwise mode. However, reversing the direction of the magnetic field applied to the optical nonreciprocal device 18 can reverse the loss magnitude relation, thereby reverse the laser oscillation direction. In other words, the optical nonreciprocal device 18 can also function as a switch for selecting oscillation direction while working as an optical isolator.

In the third embodiment, moreover, the laser light is emitted as travelling waves rather than stationary waves. The instability of wavelength in the laser operation can thus be further suppressed because travelling waves do not cause spatial hole burning in the gain.

### Variation 1 of the Third Embodiment

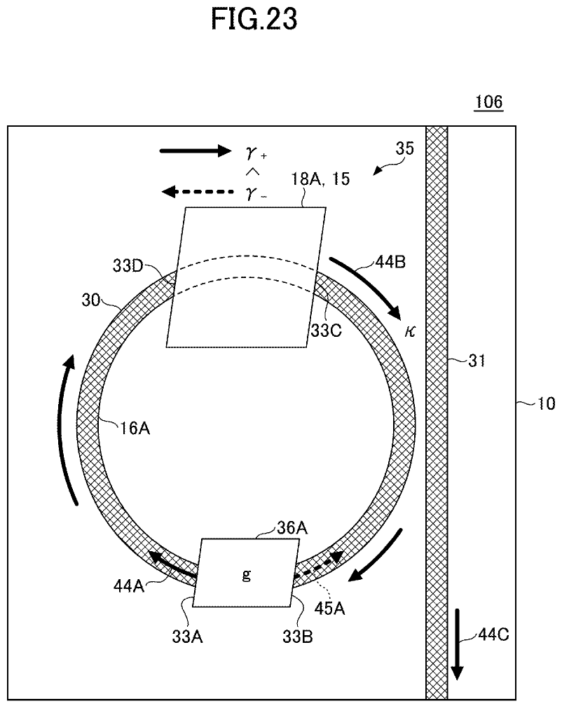

FIG. 23 is a plan view of an optical circuit according to Variation 1 of the third embodiment. As shown in FIG. 23, in the optical circuit 106 of Variation 1 of the third embodiment, the first end surface 33A and the second end surface 33B of the semiconductor laser element part 36A are oblique to a plane perpendicular to the optical axis when viewed from above. When viewed from above, the interfaces 33C and 33D, where the portion of the optical waveguide 16A in which the ferromagnet 15 of the optical nonreciprocal device 18A is provided and the portion in which the ferromagnet 15 is not provided, are oblique to a plane perpendicular to the optical axis. The other features are the same as those in the third embodiment for which description is omitted.

The light 45A emitted from the second end surface 33B of the semiconductor laser element part 36A would propagate clockwise after being reflected off the first end surface 33A, the second end surface 33B, and the interfaces 33C and 33D. This causes coupling of clockwise and counterclockwise modes. This might interfere with single mode oscillation of only clockwise mode.

According to Variation 1 of the third embodiment, when viewed from above, at least one of the first end surface 33A, the second end surface 33B, and the interfaces 33C and 33D is oblique so as not to be perpendicular to the optical axis of the ring laser 35. This makes it difficult for the light 45A reflected off the first end surface 33A, the second end surface 33B, the interfaces 33C and 33D to propagate along the optical axis. This can reduce coupling of clockwise and counterclockwise modes, facilitating single mode oscillation of only clockwise mode. The reflection of light off the first end surface 33A, the second end surface 33B, and the interfaces 33C and 33D would be reduced. For example, an antireflecting film may be disposed on the first end surface 33A, the second end surface 33B, the interfaces 33C and 33D. In the case in which another element, such as a filter or polarizer, is included in the ring resonator 30, the element may be disposed such that the end surfaces are oblique to a plane perpendicular to the optical axis, or the end surfaces are covered by an antireflecting film. The oblique angle formed by a plane perpendicular to the optical axis and the first end surface 33A, the second end surface 33B, the interfaces 33C or 33D can be, for example, Brewster's angle.

### Variation 2 of the Third Embodiment

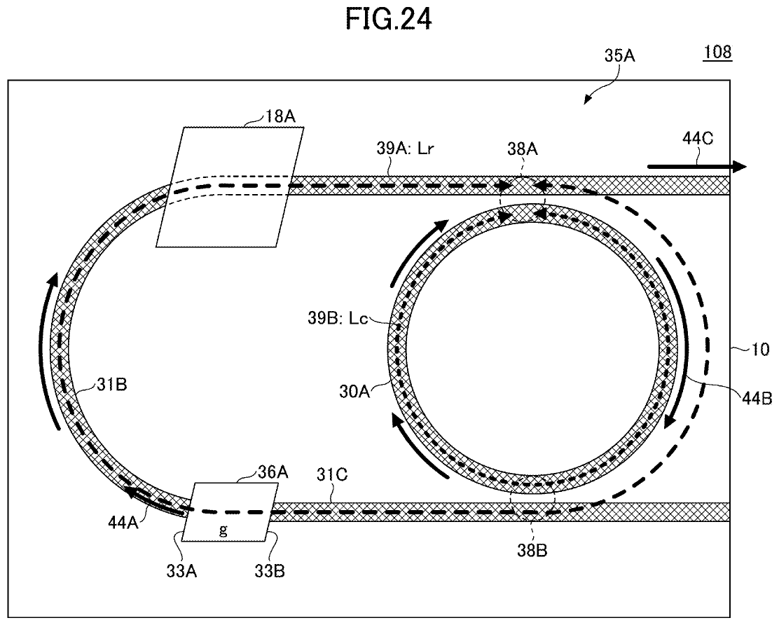

FIG. 24 is a plan view of an optical circuit according to Variation 2 of the third embodiment. As shown in FIG. 24, the optical circuit 108 of Variation 2 of the third embodiment includes a ring laser 35A. The ring laser 35A includes an optical nonreciprocal device 18A, a ring resonator 30A, a first optical waveguide 31B, a second optical waveguide 31C, and a semiconductor laser element part 36A. The ring resonator 30A, the first optical waveguide 31B, the second optical waveguide 31C, and the semiconductor layer element part 36A are disposed on the substrate 10. The first optical waveguide 31B is optically coupled to the semiconductor laser element part 36A at the first end surface 33A. The second optical waveguide 31C is optically coupled to the semiconductor laser element part 36A at the second end surface 33B. The ring resonator 30A is optically coupled to the first optical waveguide 31B at the location 38A, and optically coupled to the second optical waveguide 31C at the location 38B. The optical nonreciprocal device 18A is positioned on the first optical waveguide 31B between the semiconductor laser element part 36A and the location 38A.

The light 44A emitted by the semiconductor laser element part 36A propagates clockwise in the path 39A that returns to the semiconductor laser element part 36A via the first optical waveguide 31B, the location 38A, the ring resonator 30A, the location 38B, and the first optical waveguide 31B. In the ring resonator 30A, the light 44B propagates in the path 39B clockwise. When the length of the path 39A is Lr and the length of the path 39B is Lc, the FSR (free spectral range) of the path 39B of the ring resonator 30A is c/(n×Lc) and the FSR of the path 39A of the ring laser 35A is c/(n×Lr) in which c is speed of light and n is effective refractive index of the first optical waveguide 31B, the second optical waveguide 31C, and the ring resonator 30A. The ring laser 35A oscillates in a longitudinal mode where the FSRs respectively defined by the paths 39A and 39B overlap. This can limit the longitudinal mode for oscillation, allowing the laser light 44C of a single longitudinal mode to be emitted from one end of the first optical waveguide 31B.

As described above, in Variation 2 of the third embodiment, an optical nonreciprocal device 18 is positioned at least in one portion of the paths 39A and 39B, i.e., at least one portion of the first optical waveguide 31B and/or the second optical waveguide 31C. This allows the ring laser 35A to have a single longitudinal mode. Furthermore, using a high Q factor ring resonator 30A allows for the reduction of line width. The Q factor is preferably 10⁵ or higher or 10⁶ or higher, for example.

The locations 38A and 38B at which the ring resonator 30A couples to the first optical waveguide 31B and the second optical waveguide 31C can be set as desired. The ring resonator 30A may have multiple optically coupled ring resonators. Arranging ring resonators having different round path lengths allows for further restrictions by FSRs of the longitudinal mode, thereby reducing the probability of mode hopping.

In the foregoing, preferable modes of implementing the invention have been described in detail. However, the present invention is not limited to those embodiments described above. As such, various modifications and replacements can be made to the embodiments without deviating from the scope of the claims.

The present disclosure includes the following configurations.
(Clause 1) An optical nonreciprocal device comprising:
   a passive waveguide having a first lateral surface, a second lateral surface opposite the first lateral surface, and an upper surface connecting the first lateral surface and the second lateral surface, the passive waveguide comprising:
      a first clad,
      a second clad, and
      a core between the first clad and the second clad; and
   a ferromagnet continuously covering the first lateral surface, the second lateral surface, and the upper surface of the passive waveguide; wherein:
   in a cross section perpendicular to an optical axis of the passive waveguide, the core, a portion of the ferromagnet covering the first lateral surface, and a portion of the ferromagnet covering the second lateral surface overlap in a direction perpendicular to a stacking direction of the first clad, the core, and the second clad.
(Clause 2) The optical nonreciprocal device according to clause 1, wherein:
   the passive waveguide comprises a third clad covering side surfaces of the first clad, lateral surfaces of the core, and lateral surfaces of the second clad; and
   the ferromagnet covers lateral surfaces and an upper surface of the third clad.
(Clause 3) The optical nonreciprocal device according to clauses 1 or 2, wherein:
   the passive waveguide comprises a third clad covering lateral surfaces of the first clad, lateral surfaces of the core, and lateral surfaces of the second clad;
   the ferromagnet covers lateral surfaces and an upper surface of the third clad; and
   in the cross section perpendicular to the optical axis of the passive waveguide, a thickness of the third clad in the direction perpendicular to the stacking direction is twice a thickness of the second clad in the stacking direction at most.
(Clause 4) The optical nonreciprocal device according to clauses 2, further comprising:
   a substrate including a first region on which the passive waveguide is disposed, and a second region on which the passive waveguide is not disposed; wherein:
   the ferromagnet is continuously disposed on the passive waveguide and on the second region of the substrate, and
   in the cross section perpendicular to the optical axis of the passive waveguide, a minimum distance between the substrate and a portion of an upper surface of the ferromagnet located above the second region is less than a minimum distance between the substrate and a lower surface of the core.
(Clause 5) The optical nonreciprocal device according to any one of clauses 1 to 4, wherein the ferromagnet is formed of at least one selected from the group consisting of permalloy, permendur, PtMnSb, MnBi, MnSb, or MnAs.
(Clause 6) The optical nonreciprocal device according to any one of clauses 1 to 5, wherein the passive waveguide is formed of an amorphous material.
(Clause 7) The optical nonreciprocal device according to any one of clause 1 to 6, further comprising a magnet for magnetizing the ferromagnet.
(Clause 8) An optical circuit comprising:
   a semiconductor laser element;
   an optical waveguide optically coupled to the semiconductor laser element;
   a ring resonator optically coupled to the optical waveguide; and
   an optical nonreciprocal device according to any one of clauses 1 to 7 disposed on at least a portion of the ring resonator.
(Clause 9) The optical circuit according to any one of clause 8 wherein:
   the optical waveguide is optically coupled to an optical amplifier, and connects the semiconductor laser element and the optical amplifier; and
   the ring resonator is optically coupled to the optical waveguide.
(Clause 10) An optical circuit comprising:
   a semiconductor laser element part having a first end surface and a second end surface located opposite the first end surface;
   an optical waveguide connecting the first end surface and the second end surface; and
   an optical nonreciprocal device according to any one of clause 1 to 7 disposed in at least a portion of the optical waveguide; wherein:
   the semiconductor laser element part and the optical waveguide constitute a ring laser.
(Clause 11) The optical circuit according to clause 10, wherein at least one of the first end surface, the second end surface, and an interface between a portion of the optical waveguide on which the ferromagnet is disposed and a portion on which the ferromagnet is not disposed in a top view is oblique so as not to be perpendicular to an optical axis of the ring laser.
(Clause 12) An optical circuit comprising:
   a semiconductor laser element part having a first end surface and a second end surface located opposite the first end surface;
   a first optical waveguide optically coupled to the semiconductor laser element part at the first end surface;
   a second optical waveguide optically coupled to the semiconductor laser element part at the second end surface;
   a ring resonator optically coupled to the first optical waveguide and the second optical waveguide; and
   an optical nonreciprocal device according to any one of clauses 1 to 7 disposed in at least a portion of the first optical waveguide and/or the second optical waveguide.

### REFERENCE NUMERALS

10 substrate
12A first clad
12B second clad
12C third clad
12D underlayer
14 core
15 ferromagnet
16 passive waveguide
16A, 31, 31A optical waveguide
17A first lateral surface
17B second lateral surface
17C first upper surface
17D, 17E second upper surface
17F lower surface
18, 18A optical nonreciprocal device
20A, 20B magnet
22 conducting pad
26 antiferromagnetic film
30, 30A ring resonator
31B first optical waveguide
31C second optical waveguide
32 semiconductor laser element
33A first end surface
33B second end surface
33C, 33D border
34 optical amplifier
35, 35A ring laser
36, 36A semiconductor laser element part
51 first region
52A, 52B second region

What is claimed is:

1. An optical nonreciprocal device comprising:
a passive waveguide having a first lateral surface, a second lateral surface opposite the first lateral surface, and an upper surface connecting the first lateral surface and the second lateral surface, the passive waveguide comprising:
a first clad,
a second clad, and
a core between the first clad and the second clad; and
a ferromagnet continuously covering the first lateral surface, the second lateral surface, and the upper surface of the passive waveguide; wherein:
in a cross section perpendicular to an optical axis of the passive waveguide, the core, a portion of the ferromagnet covering the first lateral surface, and a portion of the ferromagnet covering the second lateral surface overlap in a direction perpendicular to a stacking direction of the first clad, the core, and the second clad.

2. The optical nonreciprocal device according to claim 1, wherein:
the passive waveguide comprises a third clad covering side surfaces of the first clad, lateral surfaces of the core, and lateral surfaces of the second clad; and
the ferromagnet covers lateral surfaces and an upper surface of the third clad.

3. The optical nonreciprocal device according to claim 1, wherein:
the passive waveguide comprises a third clad covering lateral surfaces of the first clad, lateral surfaces of the core, and lateral surfaces of the second clad;
the ferromagnet covers lateral surfaces and an upper surface of the third clad; and
in the cross section perpendicular to the optical axis of the passive waveguide, a thickness of the third clad in the direction perpendicular to the stacking direction is twice the value λ/n_{eff} obtained by dividing the wavelength λ of light by the effective refractive index n_{eff} of the waveguide mode, or smaller.

4. The optical nonreciprocal device according to claim 2, further comprising:
a substrate including a first region on which the passive waveguide is disposed, and a second region on which the passive waveguide is not disposed; wherein:
the ferromagnet is continuously disposed on the passive waveguide and on the second region of the substrate, and
in the cross section perpendicular to the optical axis of the passive waveguide, a minimum distance between the substrate and a portion of an upper surface of the ferromagnet located above the second region is less than a minimum distance between the substrate and a lower surface of the core.

5. The optical nonreciprocal device according to claim 3, further comprising:
a substrate including a first region on which the passive waveguide is disposed, and a second region on which the passive waveguide is not disposed; wherein:
the ferromagnet is continuously disposed on the passive waveguide and on the second region of the substrate, and
in the cross section perpendicular to the optical axis of the passive waveguide, a minimum distance between the substrate and a portion of an upper surface of the ferromagnet located above the second region is less than a minimum distance between the substrate and a lower surface of the core.

6. The optical nonreciprocal device according to claim 1, wherein the ferromagnet is formed of at least one selected from the group consisting of permalloy, permendur, PtMnSb, MnBi, MnSb, or MnAs.

7. The optical nonreciprocal device according to claim 1, wherein the passive waveguide is formed of an amorphous material.

8. The optical nonreciprocal device according to claim 2, wherein the passive waveguide is formed of an amorphous material.

9. The optical nonreciprocal device according to claim 4, wherein the passive waveguide is formed of an amorphous material.

10. The optical nonreciprocal device according to claim 1, further comprising a magnet for magnetizing the ferromagnet.

11. The optical nonreciprocal device according to claim 2, further comprising a magnet for magnetizing the ferromagnet.

12. The optical nonreciprocal device according to claim 4, further comprising a magnet for magnetizing the ferromagnet.

13. An optical circuit comprising:
a semiconductor laser element;
an optical waveguide optically coupled to the semiconductor laser element;
a ring resonator optically coupled to the optical waveguide; and
an optical nonreciprocal device according to claim 1 disposed on at least a portion of the ring resonator.

14. The optical circuit according to claim 13 wherein:
the optical waveguide is optically coupled to an optical amplifier, and connects the semiconductor laser element and the optical amplifier; and
the ring resonator is optically coupled to the optical waveguide.

15. An optical circuit comprising:
a semiconductor laser element part having a first end surface and a second end surface located opposite the first end surface;
an optical waveguide connecting the first end surface and the second end surface; and
an optical nonreciprocal device according to claim 1 disposed in at least a portion of the optical waveguide; wherein:
the semiconductor laser element part and the optical waveguide constitute a ring laser.

16. The optical circuit according to claim 15, wherein at least one of the first end surface, the second end surface, and a border between a portion of the optical waveguide on which the ferromagnet is disposed and a portion on which the ferromagnet is not disposed in a top view is oblique so as not to be perpendicular to an optical axis of the ring laser.

17. An optical circuit comprising:
a semiconductor laser element part having a first end surface and a second end surface located opposite the first end surface;
an optical waveguide connecting the first end surface and the second end surface; and
an optical nonreciprocal device according to claim 2 disposed in at least a portion of the optical waveguide; wherein:
the semiconductor laser element part and the optical waveguide constitute a ring laser.

18. The optical circuit according to claim 16, wherein at least one of the first end surface, the second end surface, and an interface between a portion of the optical waveguide on which the ferromagnet is disposed and a portion on which the ferromagnet is not disposed in a top view is oblique so as not to be perpendicular to an optical axis of the ring laser.

19. An optical circuit comprising:
a semiconductor laser element part having a first end surface and a second end surface located opposite the first end surface;
a first optical waveguide optically coupled to the semiconductor laser element part at the first end surface;
a second optical waveguide optically coupled to the semiconductor laser element part at the second end surface;
a ring resonator optically coupled to the first optical waveguide and the second optical waveguide; and
an optical nonreciprocal device according to claim 1 disposed in at least a portion of the first optical waveguide and/or the second optical waveguide.
